(19) United States
(12) Patent Application Publication
(10) Pub. No.: US 2019/0140145 A1
(43) Pub. Date: May 9, 2019

(54) Light-Emitting Device and Method for Manufacturing a Light-Emitting Device

(71) Applicant: OSRAM Opto Semiconductors GmbH, Regensburg (DE)

(72) Inventor: Tilman Rügheimer, Regensburg (DE)

(21) Appl. No.: 16/177,685

(22) Filed: Nov. 1, 2018

(30) Foreign Application Priority Data
Nov. 8, 2017 (DE) 102017126109.5

(51) Int. Cl. H01L 33/48; H01L 33/62; H01L 33/00; H01L 27/15

(52) U.S. Cl. CPC H01L 33/486; H01L 33/62; H01L 2933/0033; H01L 27/15; H01L 33/007

(57) ABSTRACT

A light-emitting device and a method for manufacturing a light-emitting device are disclosed. In an embodiment, a light-emitting device includes at least one light-emitting semiconductor body with an active layer configured to generate light and a housing comprising a carrier and a cover plate which is transparent to the light. The carrier and the cover plate are connected to each other by a surrounding metal frame and, together with the metal frame, form a hermetically sealed interior space, wherein the at least one light-emitting semiconductor body is arranged inside the interior space, and wherein the cover plate is a growth substrate on which the at least one light-emitting semiconductor body is grown.

### CROSS-REFERENCE TO RELATED APPLICATIONS

This application claims the benefit of German patent application 10 2017 126 109.5, filed on Nov. 8, 2017, which application is hereby incorporated herein by reference.

### TECHNICAL FIELD

A light-emitting device and a method for manufacturing a light-emitting device are provided.

### BACKGROUND

Nowadays, light-emitting devices with light-emitting diode chips emitting in the UV-C wavelength range are offered on the market, wherein the light-emitting diode chips are encapsulated in TO packages (TO: transistor outline) or SMT packages (SMT: surface-mounting technology) on a ceramic basis. The respective structures are relatively complex. In TO packages, a metal cap, for example, made of Kovar, is welded to the carrier part, on which the light-emitting diode chip is mounted, in order to encapsulate the light-emitting diode chip. A window made of glass material with suitable transmission is melted into the cap. In SMT packages, the encapsulation is provided by soldering a flat glass window to a ceramic housing body containing a light-emitting diode chip in a cavity. For example, a solder layer can be used between suitable metallizations on the housing body and the cover. This can be done at the level of individual devices or at the level of a compound of housing bodies.

### SUMMARY

Embodiments provide a light-emitting device. Further embodiments provide a method for manufacturing a light-emitting device.

According to at least one embodiment, a light-emitting device has a light-emitting semiconductor body. In particular, the light-emitting semiconductor body has a semiconductor layer sequence with an active layer for generating light. The semiconductor layer sequence can preferably be grown on a growth substrate by means of an epitaxial method, for example, by means of metal-organic vapor phase epitaxy (MOVPE) or molecular beam epitaxy (MBE). The semiconductor layer sequence thereby comprises semiconductor layers arranged on top of each other along an arrangement direction given by the growth direction. The layers of the semiconductor layer sequence each have a main extension plane perpendicular to the arrangement direction. In the following, directions parallel to the main plane of the semiconductor layers are referred to as lateral directions.

According to at least one further embodiment, in a method for manufacturing a light-emitting device at least one light-emitting semiconductor body is manufactured. The features and embodiments described above and below apply equally to the light-emitting device and to the method for manufacturing the light-emitting device.

Depending on the light to be generated, the light-emitting semiconductor body may have an inorganic semiconductor layer sequence based on various semiconductor material systems. In particular, the semiconductor body may be completely free of organic material and, accordingly, an inorganic semiconductor body. For example, a semiconductor layer sequence based on InₓGa_{y}Al_{1-x-y}As is suitable for long-wave, infrared to red radiation, a semiconductor layer sequence based on InₓGa_{y}Al_{1-x-y}P is suitable for red to green radiation, and a semiconductor layer sequence based on InₓGa_{y}Al_{1-x-y}N is suitable for shorter-wave visible radiation, i.e., in particular for green to blue radiation, and/or for UV radiation, wherein 0≤x≤1 and 0≤y≤1 applies in each case.

The growth substrate, on which the semiconductor layer sequence of the semiconductor body is grown, may comprise or be an insulator material or a semiconductor material. For example, the growth substrate may comprise or be sapphire or SiC. The growth substrate is particularly transparent to the light generated in the semiconductor body during operation.

The growth process can take place particularly in a wafer compound. In other words, a growth substrate is provided in the form of a wafer, i.e., a growth substrate wafer, on which the semiconductor layer sequence is grown in a large-area fashion. In a further method step, the grown semiconductor layer sequence can be structured into individual semiconductor bodies on the growth substrate.

The semiconductor layer sequence of the light-emitting semiconductor body can have a conventional pn junction, a double heterostructure, a single quantum well structure (SQW structure) or a multiple quantum well structure (MQW structure) as the active layer for generating light. The semiconductor layer sequence may include, in addition to the active layer, further functional layers and functional areas such as p- or n-doped charge-carrier transport layers, undoped or p- or n-doped confinement, cladding or waveguide layers, barrier layers, planarization layers, buffer layers, protective layers and/or electrical contacts in the form of electrode layers, and combinations thereof. In particular, the light-emitting semiconductor body may have electrical contacts for electrical contacting, for example, in the form of electrode layers, on the reverse side opposite the growth substrate. The light-emitting semiconductor body can preferably be embodied as a so-called flip chip, which can be mounted and electrically contacted on a carrier by having contacts that are all arranged on a side facing away from the growth substrate, so that the light radiation is directed away from the carrier during operation. The structures described here concerning the light-emitting semiconductor body are known to the person skilled in the art, in particular with regard to design, function and structure, and are therefore not explained in detail here.

According to another embodiment, the light-emitting device has a housing with an interior space in which the at least one light-emitting semiconductor body is arranged. In particular, the housing has a carrier and a cover plate that is transparent to the light generated by the semiconductor body during operation.

According to another embodiment, the at least one light-emitting semiconductor body is arranged in the interior space on the cover plate. The light emitted during operation by the at least one light-emitting semiconductor body can in particular be radiated outwards by the light-emitting device through the cover plate.

According to another embodiment, the cover plate is a growth substrate on which the at least one light-emitting semiconductor body is grown. In other words, the cover plate is part of a growth substrate wafer, on which the semiconductor layer sequence is grown as described above, wherein the semiconductor layer sequence can be divided into individual semiconductor bodies by structuring. In this case, the growth substrate does not only form part of a semiconductor chip which is arranged in a package formed from other components. Rather, the growth substrate itself, in the form of the cover plate, forms part of the housing in which the at least one light-emitting semiconductor body that is grown on the growth substrate is arranged.

According to another embodiment, the carrier and the cover plate are connected to each other by a surrounding metal frame, the carrier, the cover plate and the metal frame forming a hermetically sealed interior space for the at least one light-emitting semiconductor body.

In the method for manufacturing the light-emitting device, a semiconductor layer sequence can be grown in a large-area and contiguous manner, especially on a growth substrate. The semiconductor layer sequence can then be structured into separate semiconductor bodies by removing semiconductor material from the growth substrate. A metal frame can be applied around at least one of the semiconductor bodies. In particular, a respective metal frame can be applied around each of the semiconductor bodies on the growth substrate. This also includes the case that at least one metal frame is applied around at least two or more semiconductor bodies so that the corresponding light-emitting device has at least two or more light-emitting semiconductor bodies in the interior space on the cover plate. A carrier plate can then be applied to the metal frame above the growth substrate. The carrier plate and the growth substrate can each be divided between the metal frames to form a plurality of light-emitting devices.

The light-emitting device described herein can thus have an encapsulating package, which is manufactured together with the light-emitting semiconductor body in a purely wafer-based method. An individual assembly of light-emitting diode chips in prefabricated packages, as is usual in the state of the art, can thus be omitted. Rather, all elements of the light-emitting device are manufactured in a wafer compound, so that very small designs are possible in addition to the simplified process sequence.

For example, the cover plate and thus the growth substrate may comprise sapphire in a preferred embodiment or may be made of sapphire in a particularly preferred embodiment. Sapphire can have good transmission properties for light up to the UV-C range and thus form a transparent cover plate for semiconductor bodies whose semiconductor material can be selected from a variety of semiconductor materials. In a particularly preferred embodiment, the light-emitting semiconductor body can thus be intended and designed to emit light in the UV-C wavelength range during operation.

According to another embodiment, the cover plate has a surface structure on a surface facing the semiconductor body. This can mean in particular that the semiconductor body is grown directly on the surface with the surface structure. The surface structure can, for example, be a roughening in the form of regular or irregular elevations and depressions. If, as described above, the cover plate preferably comprises sapphire or is made of sapphire, the cover plate may be part of a patterned sapphire substrate (PSS).

According to another embodiment, the metal frame is directly adjacent to the cover plate. The metal frame can thus be applied directly to the surface of the cover plate facing the semiconductor body. In particular, the metal frame may be produced by an electroplating process. For this purpose, a frame-shaped metallic basic metallization can first be applied, which surrounds the at least one light-emitting semiconductor body in the lateral direction. A metallic reinforcing layer can then be applied to the basic metallization using an electroplating process. In particular, the metallic reinforcing layer may have a thickness which corresponds to the thickness of the at least one light-emitting semiconductor body, including electrical contacts, so that the contact surfaces of the electrical contacts facing away from the growth substrate and the surface of the metal frame, i.e., the surface of the reinforcing layer, facing away from the growth substrate are situated in a same plane. In order to be able to apply the metal frame directly to the cover plate, the semiconductor layer sequence can be structured as described above after the large-area growth. For this purpose, semiconductor material of the semiconductor layer sequence in areas between the semiconductor bodies, i.e., in the areas in which no semiconductor bodies are to be formed, can be completely removed from the growth substrate. In this way, in particular frame-shaped areas can be formed around the resulting semiconductor bodies, which are free of semiconductor material. In these areas the metal frame can be applied directly to the growth substrate.

According to another embodiment, the carrier comprises a ceramic material. In particular, a carrier plate with or made of a ceramic material may be provided in the manufacture of the light-emitting device. In particular, the ceramic material may exhibit high thermal conductivity and preferably a coefficient of thermal expansion as close as possible to that of the cover plate and thus to the growth substrate. By using a carrier with or made of a ceramic material, good heat dissipation can be achieved for the at least one light-emitting semiconductor body in the interior space of the housing.

According to another embodiment, the metal frame is soldered to the carrier. In particular, the carrier plate can be soldered to the metal frames applied around the semiconductor bodies during the manufacture of the light-emitting device. The carrier plate can have corresponding metallizations, also in the form of frames, which can be soldered to the metal frames.

According to a further embodiment, the carrier has at least two through-connections, by means of which the at least one light-emitting semiconductor body can be electrically contacted from the outside. For this purpose, the carrier may have through-connections in openings extending through the carrier. On the side of the carrier facing the semiconductor body as well as on the side of the carrier facing away from the semiconductor body, connection layers may be present, respectively, which are connected to each other by the through-connections. The connection layers facing the semiconductor body can be connected to the electrical contacts of the semiconductor body so that an electrical connection of the at least one light-emitting semiconductor body in the interior space of the housing is possible by means of the connection layers arranged on the outside of the carrier. The connection layers facing the semiconductor body can in particular be soldered to the electrical contacts of the semiconductor body. The soldering of the connection layers with the electrical contacts can preferably be carried out in a common process step together with the soldering of the metal frames to the carrier plate. With the aid of the connection layers arranged on the outside of the carrier, the light-emitting device can particularly preferably be surface-mountable.

According to another embodiment, the growth substrate can be thinned, especially after having mounted the carrier plate and before the method step of dividing the compound into separate light-emitting devices. This can improve the transmission properties of the cover plate formed by the growth substrate in the light-emitting device.

The light-emitting device described herein can be distinguished in particular by the fact that it is free of organic materials. In particular, the light-emitting semiconductor body, the cover plate, the carrier, the metal frame and all other components of the housing of the light-emitting device may be free of organic materials.

In the light-emitting device described herein, the growth substrate, which is used for the epitaxial growth of the semiconductor material, is also used as a housing cover in the form of the cover plate. The cover plate can be connected to the carrier to form a hermetic package, wherein the connection between carrier and cover plate can be provided at wafer level. As described above, the semiconductor material is removed between the individual semiconductor bodies during the manufacture of the semiconductor bodies and instead a metal frame, particularly preferably by galvanic reinforcement, is applied to the growth substrate, which enables a hermetic connection between the carrier and the cover plate. For example, a housing can be made possible for semiconductor bodies emitting in the UV wavelength range, wherein the housing has a high transmission and at the same time acts in a hermetically encapsulating manner in order to protect the semiconductor body from environmental influences. In particular, the UV wavelength range may be a UV-B+C wavelength range, preferably in the range from 190 nm to 315 nm, or a UV-C wavelength range, preferably in the range from 190 nm to 290 nm or even in the range from 270 nm to 290 nm. Although hermetic encapsulation is particularly advantageous for UV applications, the light-emitting device and the associated manufacturing method described herein are not limited to the UV, UV-B+C, and UV-C wavelength ranges, but are also suitable for semiconductor bodies with active layers intended and designed for generating light in other wavelength ranges.

The light-emitting device and the associated manufacturing method described herein may also have one or more of the following features and advantages:

The light-emitting device can be completely defined and manufactured in a process at wafer level, so that no serial process steps, for example, for the so-called die-attach, i.e., the assembly of semiconductor chips, as well as for the encapsulation have to be carried out, resulting in a cost advantage.

By a suitable choice of the growth substrate material described above, such as sapphire, the growth substrate and thus also the cover plate can be mechanically very stable and exhibit an excellent transmission for the wavelength range emitted by the light-emitting semiconductor body, for example, in the UV-C wavelength range.

The covering process, i.e., the arrangement of the cover plate to form the housing, can be carried out with established material systems at wafer level.

During the covering process, no glass has to be melted, as is necessary with conventional devices, so that there is no temperature risk for the semiconductor material and the remaining housing components.

Due to the design described, the light-emitting device can in particular be free of organic material. This means that apart from unintentional organic impurities, for example, due to the manufacturing process or due to handling, no organic material is present in the light-emitting device.

By roughening the growth substrate and thus the cover plate on the surface facing the semiconductor body and thus on an interface between the semiconductor material and the cover plate material, an internal total reflection can also be significantly reduced at the external interface, i.e., between the cover plate and the surrounding air, so that the decoupling efficiency can be increased. In addition, the emitted light does not have to pass through any further boundary surfaces, as would be the case with subsequently fitted lids.

The growth substrate that forms the cover plate and remains in contact with the semiconductor body can act as a heat spreader, so that heat can be dissipated to the carrier not only via the electrical contacts of the semiconductor body, but also via the metal frame.

### BRIEF DESCRIPTION OF THE DRAWINGS

Further advantages, advantageous embodiments and further developments are revealed by the embodiments described below in connection with the figures, in which:

FIGS. 1A and 1B show a light-emitting device and a method for producing a light-emitting device according to an embodiment,

FIG. 2 shows a method for manufacturing a light-emitting device according to another embodiment,

FIGS. 3A to 11 show method steps of the method shown in FIG. 2 for manufacturing a light-emitting device, and

FIGS. 12A and 12B show a method step of a method for manufacturing a light-emitting device according to another embodiment.

In the embodiments and figures, identical, similar or identically acting elements are provided in each case with the same reference numerals. The elements illustrated and their size ratios to one another should not be regarded as being to scale, but rather individual elements, such as, for example, layers, components, devices and regions, may have been made exaggeratedly large to illustrate them better and/or to aid comprehension.

### DETAILED DESCRIPTION OF ILLUSTRATIVE EMBODIMENTS

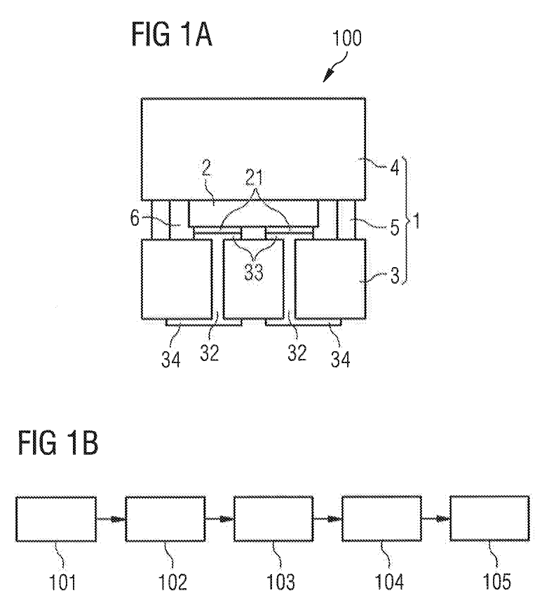

FIGS. 1A and 1B show an embodiment of a light-emitting device 100 and a method for manufacturing the light-emitting device 100.

The light-emitting device 100 has a housing 1, in which a light-emitting semiconductor body 2 is arranged, which has an active layer for generating light.

The housing 1 comprises a carrier 3 and a cover plate 4, which are connected to each other by a surrounding metal frame 5 and which form a hermetically sealed interior space 6 with the metal frame 5. In particular, the housing 1 can essentially be formed by the carrier 3, the cover plate 4 and the surrounding metal frame 5.

The cover plate 4 is transparent to the light generated by the light-emitting semiconductor body 2 during operation, so that the light-emitting device 100 can radiate light to the outside through the cover plate 4 during operation. The light-emitting semiconductor body 2 is arranged in particular on the cover plate 4, which is a growth substrate on which the light-emitting semiconductor body 2 has been grown.

For electrical contacting of the semiconductor body 2, the semiconductor body 2 has electrical contacts 21 in the form of electrode layers which are arranged on the side of the semiconductor body 2 facing away from the cover plate 4, so that the semiconductor body 2 preferably forms a flip chip. The carrier 3 has through-connections 32 and electrical connection layers 33 on the side of the carrier 3 facing the semiconductor body 2 as well as electrical connection layers 34 on the outer side of the carrier 3 facing away from the semiconductor body 2, the connection layers 33, 34 being connected to one another by the through-connections 32. The electrical contacts 21 of the light-emitting semiconductor body 2 are connected to the connection layers 33 arranged in the interior space 6, so that the light-emitting device 100 can be operated by an electrical connection of the light-emitting device 100 by means of the connection layers 34. The connection layers 34 can be particularly suitable for surface mounting of the light-emitting device 100.

As shown in FIG. 1B, a semiconductor layer sequence can be grown in a first method step 101 on a growth substrate in order to produce the light-emitting device 100. By removing semiconductor material from the growth substrate, the semiconductor layer sequence can be structured into separate semiconductor bodies in a further method step 102. In a further method step 103, a metal frame is applied to the growth substrate around at least one of the semiconductor bodies formed in this way. Then, in a further method step 104, a carrier plate is applied to the metal frame on the growth substrate. In a further method step 105, the carrier plate and the growth substrate are divided between the metal frames, which laterally enclose the semiconductor bodies, to form a plurality of light-emitting devices as the one shown in FIG. 1A.

Further and alternative features of the light-emitting device and the method for manufacturing the light-emitting device are described in connection with the following figures.

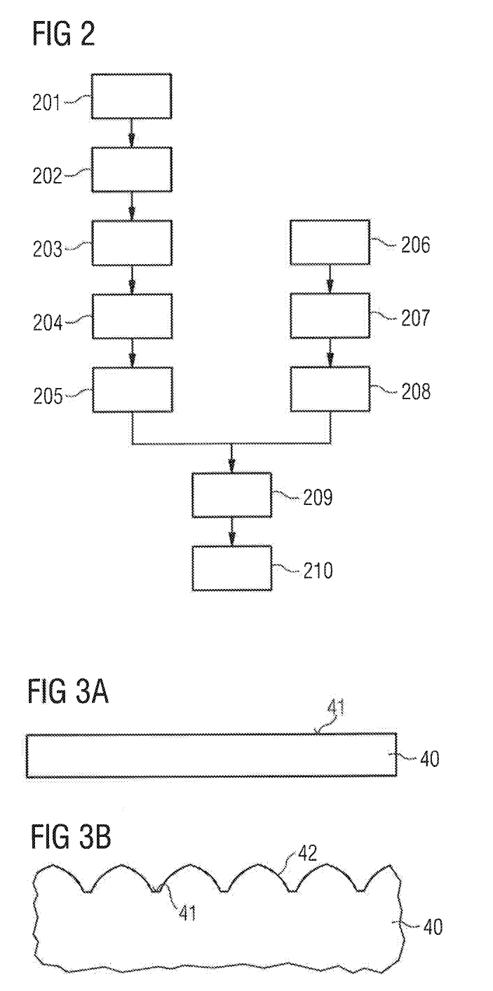

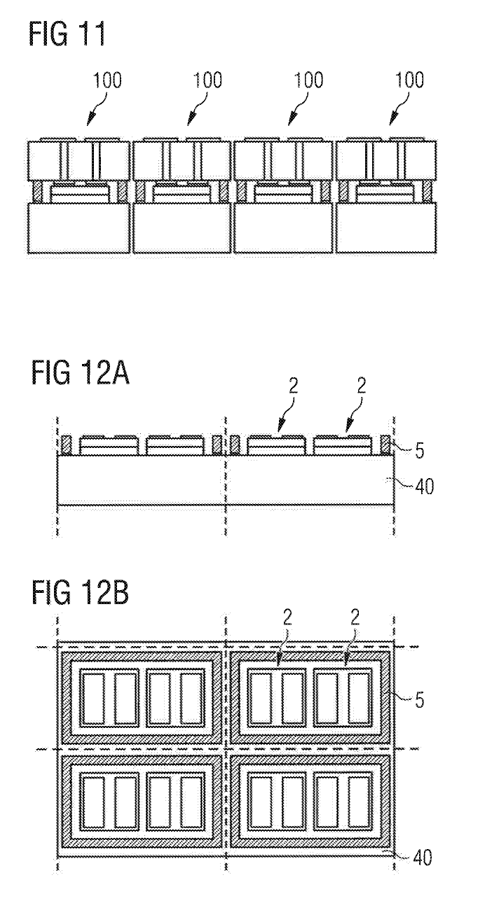

In particular, FIG. 2 shows a further example of a method for manufacturing a light-emitting device, with the method steps 201 to 210 indicated in FIG. 2 being explained in greater detail in FIGS. 3A to 11.

In the first method step 201 shown in FIG. 2, a growth substrate 40 is provided as shown in FIG. 3A. In particular, a growth substrate 40 is provided in the form of a sapphire growth substrate wafer having a surface 41 with a surface structure 42 in the form of regular elevations and depressions as shown in a detailed view in FIG. 3B. The growth substrate 40 is thus formed in particular by a structured sapphire substrate. As described in the general part above, the surface structure 42 can increase the outcoupling efficiency of the finished light-emitting device compared to a corresponding device with a flat substrate.

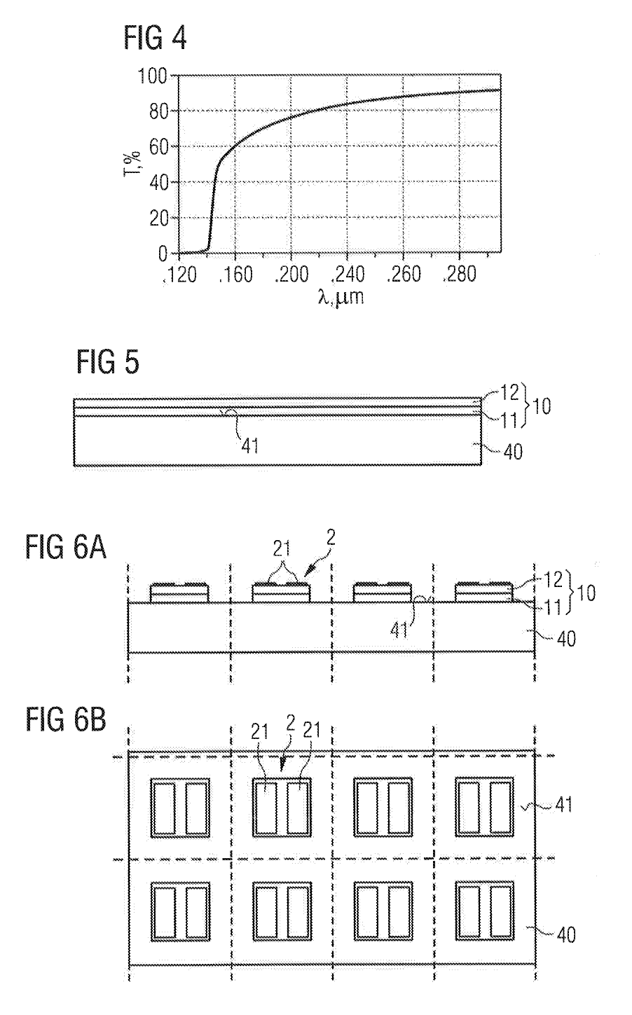

As shown in FIG. 4, sapphire has a high transmission for wavelengths up to the UV-C wavelength range. Accordingly, in connection with the following figures, a method for the production of a light-emitting device is described which can radiate light, for example, in the UV-C wavelength range. Alternatively, other wavelength ranges are also possible, which can be determined by a suitable selection of the semiconductor material used.

In the method step 202 shown in FIG. 2, on the growth substrate 40 a semiconductor layer sequence 10 is then grown on the surface 41 with the surface structure 42 in a large-area and contiguous manner, as shown in FIG. 5. As an example, the semiconductor layer sequence 10 is indicated having a buffer layer 11 and an active layer 12, wherein the growth of the active layer 12 on the growth substrate 40 can be facilitated by the buffer layer 11. The semiconductor layer sequence 10, which in the shown embodiment is based on an InAlGaN compound semiconductor material system, may also include other semiconductor layers as described in the general part above, which are necessary to form a light-emitting semiconductor body. Depending on the growth sequence, the semiconductor layer sequence 10 can end with an n-doped layer or a p-doped layer on the side facing away from the growth substrate 40.

In method step 203 shown in FIG. 2, as illustrated in FIGS. 6A and 6B, the semiconductor layer sequence 10 is then structured into separate semiconductor bodies 2 by removing semiconductor material from the growth substrate 40. FIG. 6A shows a sectional view corresponding to the views in FIGS. 3A, 3B and 5, while FIG. 6B shows a top view onto the growth surface 41. By way of example, only eight of the semiconductor bodies 2 produced in the wafer compound on the growth substrate 40 are shown. Here and in the following, the dotted lines mark later-used separation areas along which the compound is divided into individual devices.

The removal of the semiconductor material between the resulting semiconductor bodies 2 can in particular be carried out by an etching method in which the surface 41 of the growth substrate 40 is removed in frame-shaped areas laterally surrounding the semiconductor bodies, so that these areas are free of the semiconductor material.

Each of the semiconductor bodies 2 is provided with electrical contacts 21 in the form of electrode layers on the side facing away from the growth substrate 40, which, as described above, are intended and designed for the electrical contacting of the semiconductor bodies 2. In addition, other method steps as known from chip manufacture can be carried out, such as mesa etching and/or the application of passivation and/or mirror layers.

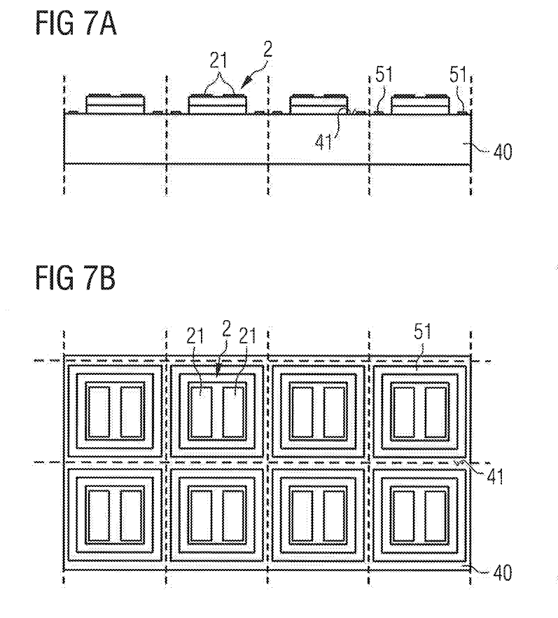

In the further method step 204 shown in FIG. 2, a frame-shaped basic metallization 51 is applied laterally around the semiconductor bodies 2, as illustrated in FIGS. 7A and 7B again in a sectional view and a top view. In the example shown, a frame is formed around each of the semiconductor bodies 2 by the basic metallization 51. The basic metallization 51 fulfils the functions of an adhesion promoter to the growth substrate 40, of a diffusion barrier and of providing a seed layer for the electroplating step described in the following. The basic metallization 51 can have one or preferably several layers. For example, the basic metallization may include or consist of a stack of layers of Ti, Ni, Pt, Pd and/or Au. Particularly preferably, the basic metallization 51 of the growth substrate may comprise or be, for example, a Ti/Pt/Au, a Ti/Pd/Au, a Ti/Ni/Au or a Ti/Ni/Cu layer stack, especially with a thickness of several 100 nm.

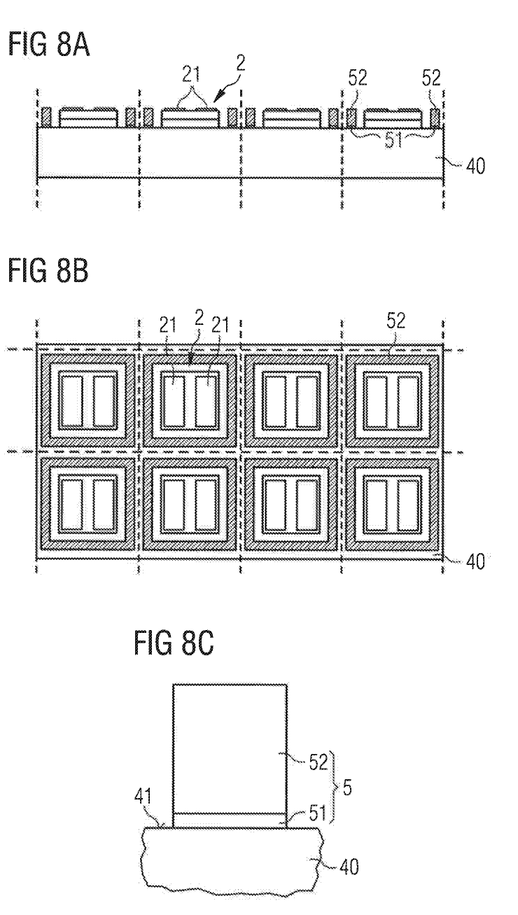

In the further method step 205 shown in FIG. 2, as shown correspondingly in FIGS. 8A to 8C, a metallic reinforcing layer 52 is applied to the frame formed by the basic metallization 51 by means of an electroplating process, whereby, as shown in detail in FIG. 8C in an enlarged section, a metal frame 5 surrounding the semiconductor bodies 2 is formed. The galvanic reinforcement is carried out to a height which corresponds approximately to the height of the semiconductor bodies including the electrical contacts 21, so that the electrical contacts 21 of the semiconductor bodies 2 and the metal frames 5 end at the same height when viewed from the growth substrate 40. The semiconductor bodies 2 can usually have a thickness of a few micrometers, especially in the range from 5 μm to 7 μm, so that the metal frame 5 can have a corresponding thickness. The reinforcing layer 52 can, for example, be manufactured by Cu-, Ni- or Au-based electroplating.

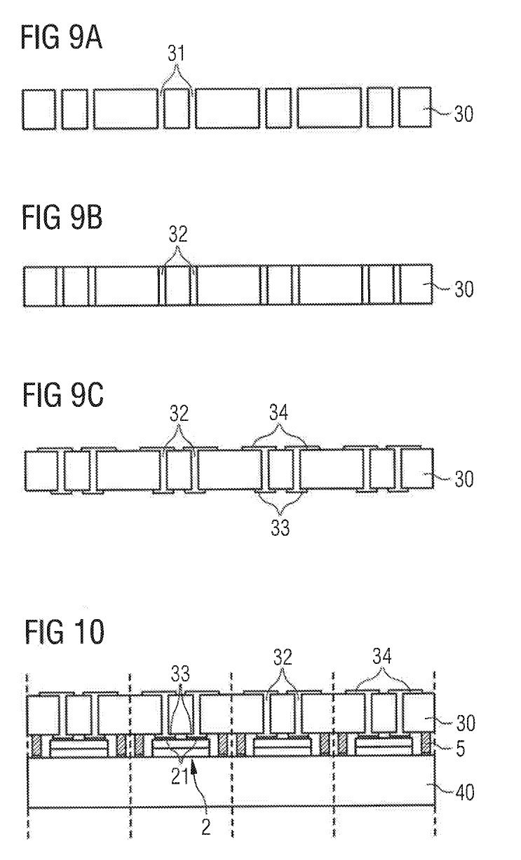

In step 206 shown in FIG. 2, a support plate 30 is provided as illustrated in FIG. 9A. The carrier plate 30 can in particular be embodied as a ceramic substrate with high thermal conductivity. Furthermore, it can be particularly advantageous if the carrier plate 30 has a thermal expansion coefficient that is as close as possible to that of the growth substrate 40, i.e., as close as possible to the thermal expansion coefficient of sapphire in the shown embodiment. For example, Al₂O₃, AlN or SiC can be suitable ceramic materials for this purpose.

The carrier plate 30 is provided with openings 31, which extend through the carrier plate 30. In the further method step 207 shown in FIG. 2, metallic material, such as copper, is filled into the openings 31 to form through-connections 32, as illustrated in FIG. 9B.

Further method step 208 of FIG. 2 shows, as illustrated in FIG. 9C, that electrical connection layers 33, 34 are applied to the surfaces of the carrier plate 30, which are connected to each other in pairs by the through-connections 32. The connection layers 33 are intended for establishing a connection to the electrical contacts 21 of the semiconductor body 2, while the connection layers 34 form contact structures which are intended in particular for a later SMT assembly, for example, on a metal core board.

In method step 209 shown in FIG. 2, as illustrated in FIG. 10, the growth substrate 40 carrying the semiconductor bodies 2 and the metal frame 5 is connected at wafer level to the carrier plate 30 having the through-connections 32 and the connection layers 33, 34. This can be done in particular by a soldering process, for example, by means of an AuSn solder, with which the connection layers 33 are connected to the electrical contacts 21. The metal frames 5 can be soldered to the carrier plate 30, which may preferably have corresponding frame-shaped metallizations (not shown). The frame-shaped metallizations on the carrier plate 30 may contain one or more of the materials described above for the basic metallization, e.g., a Ti/Cu/Au layer stack. Subsequently or even before joining, the growth substrate 40 can also be thinned on the side facing away from the semiconductor bodies 2.

The production of the solder connections between the metal frames 5 and the carrier plate 30 as well as between the electrical contacts 21 and the connection layers 33 can preferably be carried out in the same method step. The soldering method can take place in a gas atmosphere, for example, in an atmosphere with dry air, nitrogen gas or forming gas, in the latter case a mixture of nitrogen or argon with hydrogen. Accordingly, such a gas atmosphere may be present in the interior spaces enclosed by the metal frames 5 in which the light-emitting semiconductor bodies 2 are arranged. Each of the interior spaces can be hermetically sealed by the respective soldered connection.

In step 210 shown in FIG. 2, as illustrated in Figure ii, the thus formed device compound is divided into individual light-emitting devices 100 along the previously indicated separation lines, by dividing the support plate 30 and the growth substrate 40 so that the resulting portions of the support plate 30 form supports and the resulting portions of the growth substrate 40 form cover plates of the light-emitting devices 100. Subsequently, for example, the light-emitting devices produced in this way can be tested in a further method step.

FIGS. 12A and 12B show a method step of a method for producing a light-emitting device according to a further embodiment corresponding to the method step described in conjunction with FIGS. 8A to 8C. In comparison to the previous embodiment, a metal frame 5 is not applied individually around each semiconductor body 2. Alternatively, more than two semiconductor bodies 2 can each be enclosed by a metal frame, so that in the resulting light-emitting devices two or more light-emitting semiconductor bodies can be arranged in the interior space of the housing on the cover plate and electrically connected via through-connections in the carrier in the manner described above.

The features and embodiments described in connection with the figures can be combined with one another according to further embodiments, even if not all combinations are explicitly described. In addition, the embodiments described in connection with the figures may have alternative or additional features according to the description in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

What is claimed is:

1. Light-emitting device, comprising:
at least one light-emitting semiconductor body with an active layer configured to generate light;
a housing comprising a carrier and a cover plate which is transparent to the light,
wherein the carrier and the cover plate are connected to each other by a surrounding metal frame and, together with the metal frame, form a hermetically sealed interior space,
wherein the at least one light-emitting semiconductor body is arranged inside the interior space, and
wherein the cover plate is a growth substrate on which the at least one light-emitting semiconductor body is grown.

2. The device according to claim 1, wherein the cover plate comprises sapphire.

3. The device according to claim 1, wherein the cover plate has a surface structure on a surface facing the at least one light-emitting semiconductor body.

4. The device according to claim 1, wherein the metal frame is directly adjacent to the cover plate.

5. The device according to claim 1, wherein the metal frame is soldered to the carrier.

6. The device according to claim 1, wherein the carrier has at least two through-connections through which the at least one light-emitting semiconductor body is electrically contactable from an outside.

7. The device according to claim 6, wherein the at least one light-emitting semiconductor body has at least two electrical contacts on a side remote from the cover plate, and each of the at least two electrical contacts is electrically conductively connected to one of the at least two through-connections, respectively.

8. The device according to claim 1, wherein the at least one light-emitting semiconductor body is a flip chip.

9. The device according to claim 1, wherein the at least one light-emitting semiconductor body is configured to emit light in a UV-C wavelength range during operation.

10. The device according to claim 1, wherein at least two light-emitting semiconductor bodies are arranged in the interior space on the cover plate.

11. The device according to claim 1, wherein the light-emitting device is free of organic materials.

12. A method for manufacturing a light-emitting device, the method comprising:
growing a semiconductor layer sequence in a large-area and in a contiguous fashion on a growth substrate;
structuring the semiconductor layer sequence into separate semiconductor bodies by removing a semiconductor material on the growth substrate;
applying metal frames around the semiconductor bodies, wherein each of the metal frames is applied around at least one of the semiconductor bodies, respectively;
placing a carrier plate over the growth substrate on the metal frames; and
dividing the carrier plate and the growth substrate between the metal frames so as to form a plurality of light-emitting devices.

13. The method according to claim 12, further comprising:
completely removing the semiconductor material of the semiconductor layer sequence between the semiconductor bodies from the growth substrate; and
directly applying the metal frames to the growth substrate.

14. The method according to claim 12, wherein applying the metal frames around the semiconductor bodies comprises, for each metal frame, applying a frame-shaped basic metallization and applying a metallic reinforcing layer to the basic metallization by an electroplating method.

15. The method according to claim 12, wherein the carrier plate is soldered to the metal frames.
